(19) United States
(12) Patent Application Publication
(10) Pub. No.: US 2023/0163733 A1
(43) Pub. Date: May 25, 2023

(54) ULTRA-HIGH FREQUENCY AMPLIFIER

(71) Applicant: ELECTRONICS AND TELECOMMUNICATIONS RESEARCH INSTITUTE, Daejeon (KR)

(72) Inventors: Sunwoo KONG, Daejeon (KR); Bong Hyuk Park, Daejeon (KR); Hui Dong Lee, Daejeon (KR); Seunghyun Jang, Daejeon (KR); Seok Bong Hyun, Daejeon (KR)

(21) Appl. No.: 17/939,648

(22) Filed: Sep. 7, 2022

(30) Foreign Application Priority Data
Nov. 19, 2021 (KR) 10-2021-0160481
Jul. 11, 2022 (KR) 10-2022-0085097

(51) Int. Cl. H03F 3/193

(52) U.S. Cl. CPC H03F 3/193; H03F 2200/451; H03F 2200/09; H03F 2200/21

(57) ABSTRACT

Disclosed is an ultra-high frequency amplifier which includes a first conductor connected to an amplifier input terminal to receive an RF signal applied to the amplifier input terminal, a second conductor parallel to a first portion of the first conductor, a third conductor separated from the second conductor and parallel to a second portion of the first conductor, and a transistor including a gate terminal connected to one end of the second conductor, a first terminal connected to one end of the third conductor, and a second terminal connected to an amplifier output terminal, wherein the first conductor and the second conductor form a first balun to output a first balance signal based on the RF signal, the first conductor and the third conductor form a second balun to output a second balance signal based on the RF signal.

### CROSS-REFERENCE TO RELATED APPLICATIONS

This application claims priority under 35 U.S.C. § 119 to Korean Patent Application Nos. 10-2021-0160481 filed on Nov. 19, 2021, and 10-2022-0085097 filed on Jul. 11, 2022, in the Korean Intellectual Property Office, the disclosures of which are incorporated by reference herein in their entireties.

### BACKGROUND

Embodiments of the present disclosure described herein relate to an ultra-high frequency amplifier, and more particularly, relate to an ultra-high frequency amplifier for amplifying a high frequency signal through a plurality of baluns.

An amplifier is a component closest to an antenna that processes a high-frequency signal in a radio transmission/reception system. A high-frequency signal is reflected and is not transmitted to a next component unless there is a match between the components. An amplifier may require a matching circuit to transmit a high-frequency signal.

However, the high-frequency signal may be greatly affected by the parasitic component of a matching circuit and may be leaked or attenuated. As the operating frequency increases, there may be a limit to the normal operation of an amplifier. An amplifier may not provide a gain at a high operating frequency, such as terahertz, and may cause a loss.

### SUMMARY

Embodiments of the present disclosure provide an ultra-high frequency amplifier capable of amplifying a high-frequency signal in an ultra-high frequency band.

According to an embodiment, an ultra-high frequency amplifier includes a first conductor connected to an amplifier input terminal to receive an RF signal applied to the amplifier input terminal, a second conductor parallel to a first portion of the first conductor, a third conductor separated from the second conductor and parallel to a second portion of the first conductor, and a transistor including a gate terminal connected to one end of the second conductor, a first terminal connected to one end of the third conductor, and a second terminal connected to an amplifier output terminal, wherein the first conductor and the second conductor form a first balun to output a first balance signal based on the RF signal, the first conductor and the third conductor form a second balun to output a second balance signal based on the RF signal, and the first balance signal and the second balance signal output from the first balun and the second balun, respectively, control an amount of drain-source current of the transistor.

According to an embodiment, the ultra-high frequency amplifier may further include an inductor connected between the gate terminal of the transistor and one end of the second conductor.

According to an embodiment, the ultra-high frequency amplifier may further include an input resistor having one end connected to the gate terminal of the transistor and an opposite end connected to a gate bias terminal to which a gate input voltage is applied.

According to an embodiment, a phase of the first balance signal may be opposite to a phase of the second balance signal.

According to an embodiment, a length of the second conductor may be different from a length of the third conductor.

According to an embodiment, one end of the second conductor may be connected to the gate terminal of the transistor, and the ultra-high frequency amplifier may further include an input resistor having one end connected to an opposite end of the second conductor and an opposite end connected to a gate bias terminal to which a gate input voltage is applied.

According to another embodiment, an ultra-high frequency amplifier includes a first conductor connected to an amplifier input terminal to receive an RF signal applied to the amplifier input terminal, a second conductor parallel to a first portion of the first conductor, a third conductor separated from the second conductor and parallel to a second portion of the first conductor, a fourth conductor parallel to a third portion of the first conductor, a fifth conductor separated from the fourth conductor and parallel to a fourth portion of the first conductor, a first transistor including a first terminal connected to one end of the second conductor, a gate terminal connected to one end of the fourth conductor, and a second terminal connected to an amplifier output terminal, and a second transistor including a first terminal connected to one end of the third conductor, a gate terminal connected to one end of the fifth conductor, and a second terminal connected to the amplifier output terminal, wherein the first conductor and the second conductor form a first balun to output a first balance signal based on the RF signal, the first conductor and the third conductor form a second balun to output a second balance signal based on the RF signal, the first conductor and the fourth conductor form a third balun to output a third balance signal based on the RF signal, the first conductor and the fifth conductor form a fourth balun to output a fourth balance signal based on the RF signal, the first balance signal and the third balance signal output from the first balun and the third balun, respectively, control an amount of drain-source current of the first transistor, and the second balance signal and the fourth balance signal output from the second balun and the fourth balun, respectively, control an amount of drain-source current of the second transistor.

According to an embodiment, the ultra-high frequency amplifier may further include a first inductor connected between the gate terminal of the first transistor and one end of the fourth conductor, and a second inductor connected between the gate terminal of the second transistor and one end of the fifth conductor.

According to an embodiment, the ultra-high frequency amplifier may further include a first input resistor having one end connected to the gate terminal of the first transistor and an opposite end connected to a gate bias terminal to which a gate input voltage is applied, and a second input resistor having one end connected to the gate terminal of the second transistor and an opposite end connected to the gate bias terminal to which the gate input voltage is applied.

According to an embodiment, a phase of the first balance signal may be opposite to a phase of the third balance signal.

According to an embodiment, a phase of the second balance signal may be opposite to a phase of the fourth balance signal.

According to an embodiment, a length of the second conductor may be different from a length of the fourth conductor.

According to an embodiment, a length of the third conductor may be different from a length of the fifth conductor.

According to an embodiment, one end of the fourth conductor may be connected to the gate terminal of the first transistor, wherein one end of the fifth conductor is connected to the gate terminal of the second transistor, and the ultra-high frequency amplifier may further include a first input resistor having one end connected to an opposite end of the fourth conductor and an opposite end connected to a gate bias terminal to which a gate input voltage is applied, and a second input resistor having one end connected to an opposite end of the fifth conductor and an opposite end connected to the gate bias terminal to which the gate input voltage is applied.

According to the embodiments of the present disclosure, there is provided an ultra-high frequency amplifier capable of amplifying a signal of a very high frequency band through a plurality of baluns. The ultra-high frequency amplifier may provide a gain at a high operating frequency, such as terahertz. Accordingly, the performance of the ultra-high frequency amplifier may be improved.

### BRIEF DESCRIPTION OF THE FIGURES

The above and other objects and features of the present disclosure will become apparent by describing in detail embodiments thereof with reference to the accompanying drawings.

FIG. 1 is a diagram illustrating an ultra-high frequency amplifier including a matching circuit.

FIG. 2 is a diagram illustrating an ultra-high frequency amplifier according to a first embodiment of the present disclosure.

FIG. 3 is a diagram illustrating an ultra-high frequency amplifier according to a second embodiment of the present disclosure.

FIG. 4A is a graph comparing the maximum allowable gains (Gmax) of the ultra-high frequency amplifiers of FIGS. 1 and 2.

FIG. 4B is a graph comparing the maximum frequencies (Fmax1 and Fmax2) when the maximum allowable gains (Gmax) of the ultra-high frequency amplifiers of FIGS. 1 and 2 are zero.

FIG. 4C is a graph comparing current gains (Imax) of the ultra-high frequency amplifiers of FIGS. 1 and 2.

FIG. 4D is a graph comparing the maximum frequencies (Ft1 and Ft2) when the current gains (Imax) of the ultra-high frequency amplifiers of FIGS. 1 and 2 are zero.

FIG. 5 is a diagram illustrating an ultra-high frequency amplifier according to a third embodiment of the present disclosure.

FIG. 6 is a diagram illustrating an ultra-high frequency amplifier according to a fourth embodiment of the present disclosure.

FIG. 7 is a flowchart illustrating a method of operating the ultra-high frequency amplifier according to the first embodiment of the present disclosure.

### DETAILED DESCRIPTION

Hereinafter, various embodiments of the present disclosure will be described clearly and in detail, so that those skilled in the art can easily carry out the present disclosure.

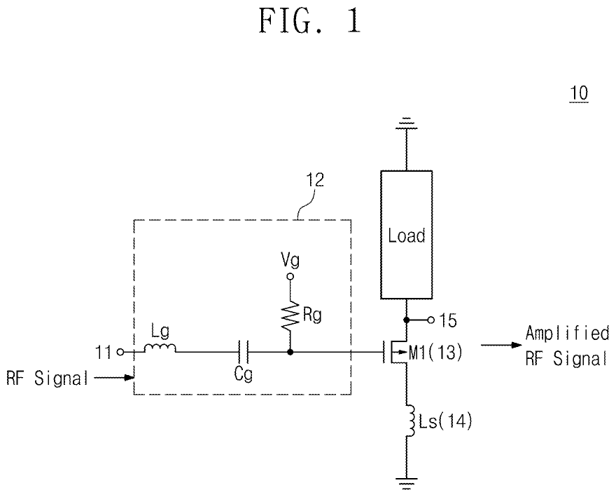

FIG. 1 is a diagram showing an ultra-high frequency amplifier 10 including a matching circuit 12.

Referring to FIG. 1, the ultra-high frequency amplifier 10 may include an amplifier input terminal 11, the matching circuit 12 having an input terminal connected to the amplifier input terminal 11, a transistor 13 including a gate terminal connected to an output terminal of the matching circuit 12, a second terminal connected to an amplifier output terminal 15 and a first terminal, a source inductor (Ls) 14 connected to the first terminal of the transistor 13, and an amplifier output terminal 15.

The amplifier input terminal 11 may receive an RF signal transmitted from an antenna (not shown) of an external wireless transmission/reception system (not shown). The external wireless transmission/reception system (not shown) may be an amplifier operating in a specified frequency band.

The matching circuit 12 may include an inductor Lg, a capacitor Cg, and an input resistor Rg. One end of the inductor Lg may be connected to the amplifier input terminal 11, and an opposite end of the inductor Lg may be connected to one end of the capacitor Cg. An opposite end of the capacitor Cg may be connected to the gate terminal of the transistor 13. One end of the input resistor Rg may be connected to an opposite end of the capacitor Cg and the gate terminal of the transistor 13, and an opposite end of the input resistor Rg may be connected to a gate bias terminal to which a gate input voltage Vg is applied.

An input power source (not shown) may apply the gate input voltage Vg through the gate bias terminal. The input power source (not shown) may control the gate input voltage Vg such that the frequency of an RF signal input through the amplifier input terminal 11 corresponds to a resonance frequency at which the inductor Lg and the capacitor Cg included in the matching circuit 12 are matched.

The transistor 13 may be one of an n-channel type MOSFET, a p-channel type MOSFET, or a HEMT. Hereinafter, the transistor 13 is described as a field effect transistor (FET), but the technical concept of the present disclosure is not limited to an FET.

The transistor 13 may serve as an amplifier for amplifying the RF signal input through the amplifier input terminal 11, or as a switch for switching to allow the RF signal to be output from the amplifier output terminal 15 when the gate-source voltage is greater than or equal to a threshold voltage.

The transistor 13 may convert a gate input voltage into a current based on an input RF signal. The input RF signal may adjust a drain-source current amount of the transistor 13 based on the gate input voltage Vg.

The source inductor (Ls) 14 may have one end connected to the first terminal of the transistor 13 and an opposite end connected to a ground terminal. As the inductance value of the source inductor (Ls) 14 increases, the current gain of the ultra-high frequency amplifier 10 may increase. As the value of the source inductor (Ls) 14 increases, the maximum frequency for generating a current gain in the ultra-high frequency amplifier 10 may increase.

One end of a load may be connected to the amplifier output terminal 15, and an opposite end may be connected to a power voltage terminal. The input power source (not shown) may apply an input voltage to the load through the power voltage terminal. The load may include at least one of a resistor, an inductor and a capacitor, or a combination thereof.

The amplifier output terminal 15 may be a terminal for outputting the RF signal amplified by the transistor 13. The amplified RF signal output from the amplifier output terminal 15 may be transmitted to another external wireless transmission/reception system (not shown) through an antenna (not shown).

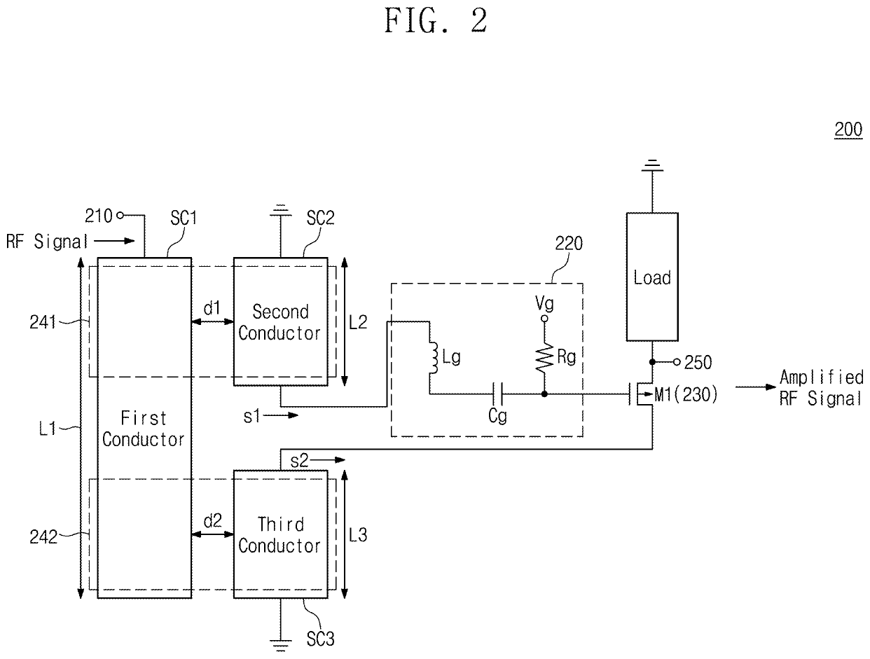

FIG. 2 is a diagram illustrating an ultra-high frequency amplifier 200 according to a first embodiment of the present disclosure. Referring to FIG. 2, the ultra-high frequency amplifier 200 may include an amplifier input terminal 210, a matching circuit 220, a transistor 230 including a gate terminal connected to an output terminal of the matching circuit 220, a second terminal connected to an amplifier output terminal 250 and a first terminal, a first balun 241, a second balun 242, and the amplifier output terminal 250.

For example, the amplifier input terminal 210, the matching circuit 220, the transistor 230, and the amplifier output terminal 250 of FIG. 2 correspond to the amplifier input terminal 11, the matching circuit 12, and the transistor 13, and the amplifier output terminal 15 of FIG. 1. Accordingly, overlapping descriptions of similar operations for each corresponding component will be omitted.

The ultra-high frequency amplifier 200 may include one or more conductors. For example, FIG. 2 illustrates the configurations of a first conductor SC1, a second conductor SC2 and a third conductor SC3, but the embodiments are not limited thereto and may include four or more conductors.

One end of the first conductor SC1 may be connected to the amplifier input terminal 210 to receive an RF signal applied to the amplifier input terminal 210. An opposite end of the first conductor SC1 may be in an open state.

The second conductor SC2 may be arranged parallel to a first portion of the first conductor SC1. In detail, the second conductor SC2 may be arranged on a first side surface of the first conductor SC1, and may be arranged at a predetermined distance d1 from the first side surface of the first conductor SC1. One end of the second conductor SC2 may be connected to a ground terminal, and an opposite end of the second conductor SC2 may be connected to an input terminal of the matching circuit 220.

Similarly, the third conductor SC3 may be arranged parallel to a second portion of the first conductor SC1. In detail, the third conductor SC3 may be arranged separately from the second conductor SC2, arranged on the first side surface of the first conductor SC1 while being spaced apart from the first side surface of the first conductor SC1 by a predetermined distance d2. One end of the third conductor SC3 may be connected to a ground terminal, and an opposite end of the third conductor SC3 may be connected to the first terminal of the transistor 230.

The predetermined distance d1 between the first conductor SC1 and the second conductor SC2 may be the same as or different from the predetermined distance d2 between the first conductor SC1 and the third conductor SC3. The ultra-high frequency amplifier 200 may adjust the input impedance of the transistor 230 by adjusting the predetermined distance d1 and the predetermined distance d2.

The length L2 of the second conductor SC2 may be the same as or different from the length L3 of the third conductor SC3. The ultra-high frequency amplifier 200 may adjust the length L1 of the first conductor SC1, the length L2 of the second conductor SC2, and the length L3 of the third conductor SC3 to adjust the input impedance of the transistor 230.

The first conductor SC1 and the second conductor SC2 may form the first balun 241. The first balun 241 may output a first balance signal s1 based on the RF signal input to the amplifier input terminal 210. The first balance signal s1 may be output through an opposite end of the second conductor SC2.

The first conductor SC1 and the third conductor SC3 may form the second balun 242. The RF signal input to the amplifier input terminal 210 may be provided to the second balun 242 through the first conductor SC1. The second balun 242 may output a second balance signal s2 based on the RF signal input to the amplifier input terminal 210. The second balance signal s2 may be output through an opposite end of the third conductor SC3.

The phase of the first balance signal s1 output from the first balun 241 may precede the phase of the second balance signal s2 output from the second balun 242 by 180 degrees. Alternatively, the phase of the second balance signal s2 output from the second balun 242 may precede the phase of the first balance signal s1 output from the first balun 241 by 180 degrees.

In this case, the first balance signal s1 and the second balance signal s2 may adjust the drain-source current amount of the transistor 230 based on the gate input voltage Vg, and may reduce the amount of current leaked due to a parasitic component (internal capacitance, not shown) of the transistor 230 by adjusting the drain-source current amount of the transistor 230.

The transistor 230 may amplify the RF signal based on the first balance signal s1 output from the first balun 241 and the second balance signal s2 output from the second balun 242.

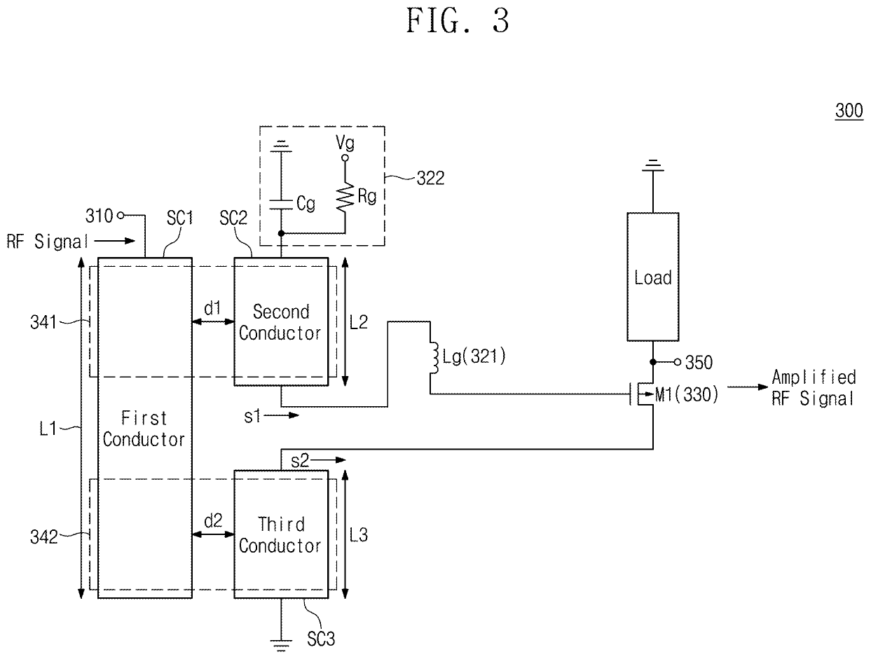

FIG. 3 is a diagram illustrating an ultra-high frequency amplifier 300 according to a second embodiment of the present disclosure. Referring to FIG. 3, an amplifier input terminal 310, an inductor (Lg) 321, an RC circuit 322, a transistor 330, a first balun 341, a second balun 342, and an amplifier output terminal 350 may be included.

For example, the amplifier input terminal 310, the transistor 330, the first balun 341, the second balun 342, and the amplifier output terminal 350 of FIG. 3 correspond to the amplifier input terminal 210, the transistor 230 , the first balun 241, the second balun 242, and the amplifier output terminal 250 of FIG. 2. Accordingly, overlapping descriptions of similar operations for each corresponding component will be omitted.

The inductor (Lg) 321 may have one end connected to an opposite end of the second conductor SC2 and an opposite end connected to the gate terminal of the transistor 330. The inductor (Lg) 321 may have a value matching the parasitic component (internal capacitance, not shown) of the transistor 330.

An input power source (not shown) may apply the gate input voltage Vg through a gate bias terminal. The input power supply source (not shown) may adjust the gate input voltage Vg to allow the frequency of the RF signal input through the amplifier input terminal 310 to correspond to the resonance frequency at which the parasitic components (internal capacitance, not shown) of the inductor (Lg) 321 and the transistor 330 are matched.

The RC circuit 322 may include an input resistor Rg and a capacitor Cg. One end of the input resistor Rg may be connected to one end of the second conductor SC2 and one end of the capacitor Cg, and an opposite end of the input resistor Rg may be connected to the gate bias terminal to which the gate input voltage Vg is applied. An opposite end of the capacitor Cg may be connected to a ground terminal.

The first conductor SC1 and the second conductor SC2 may form the first balun 341. The first balun 341 may output a first balance signal s1 based on the RF signal input to the amplifier input terminal 310. The phase of the first balance signal s1 may vary according to values of the input resistor Rg and the capacitor Cg included in the RC circuit 322.

The phase of the first balance signal s1 output from the first balun 341 that varies according to the values of the input resistor Rg and the capacitor Cg may precede the phase of the second balance signal s2 output from the second balun 342 by 180 degrees. Alternatively, the phase of the second balance signal s2 output from the second balun 342 may precede the phase of the first balance signal s1 output from the first balun 341, which varies according to the values of the input resistor Rg and the capacitor Cg, by 180 degrees.

In this case, the first balance signal s1 and the second balance signal s2 may adjust the drain-source current amount of the transistor 330 based on the gate input voltage Vg.

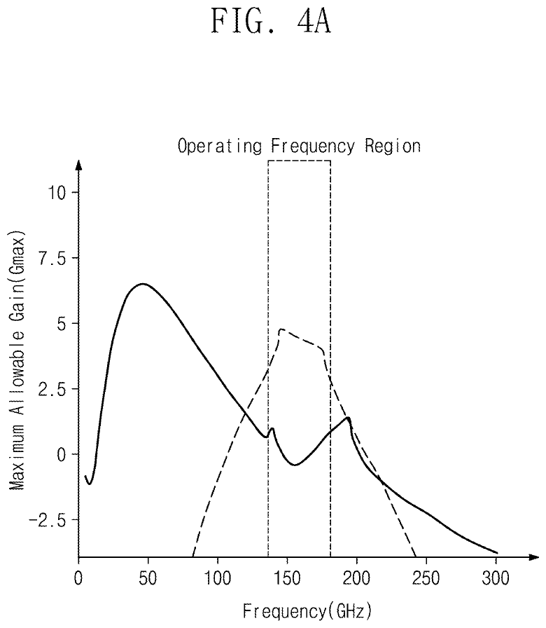

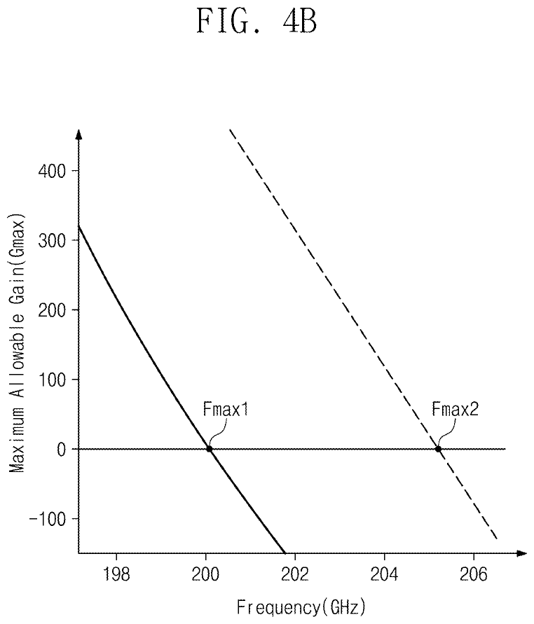

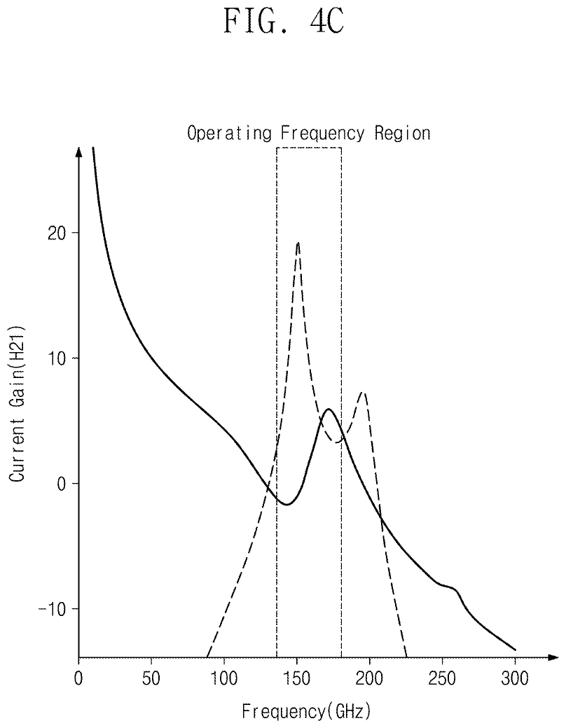

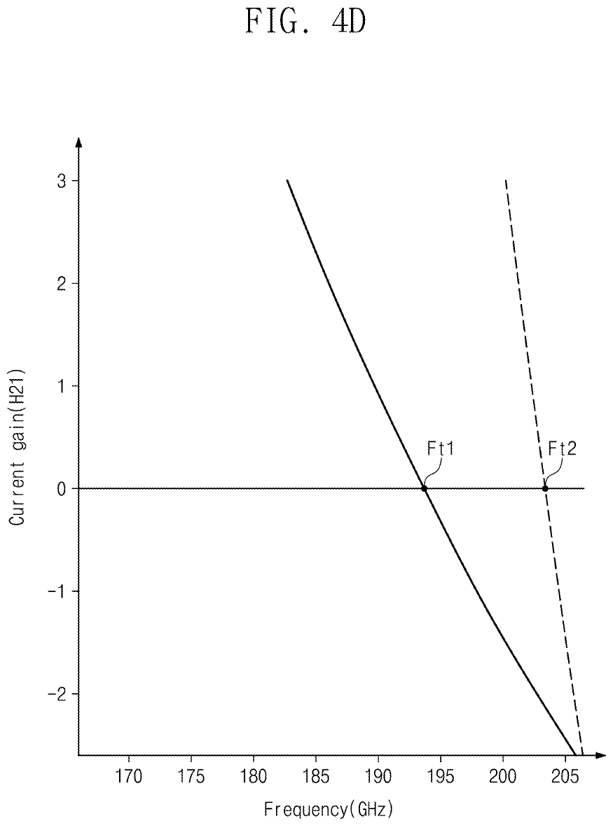

FIG. 4A is a graph comparing the maximum allowable gains (Gmax) of the ultra-high frequency amplifiers 10 and 200 of FIGS. 1 and 2.

In FIG. 4A, the horizontal axis may indicate a frequency, and the unit may be GHz. The vertical axis may indicate the maximum allowable gain (Gmax), and the unit may be dB.

Referring to FIGS. 1, 2 and 4A, the solid line shows the maximum allowable gain (Gmax) of the ultra-high frequency amplifier 10 of FIG. 1. The maximum allowable gain (Gmax) may refer to a ratio of the power of the amplified RF signal at the amplifier output terminal 15 to the power of the RF signal input to the amplifier input terminal 11. The dotted line shows the maximum allowable gain (Gmax) of the ultra-high frequency amplifier 200 of FIG. 2.

As indicated by the solid and dotted lines, in the operating frequency region (frequency band between 140 GHz and 180 GHz), the maximum allowable gain (Gmax) of the ultra-high frequency amplifier 200 of FIG. 2 may have a value higher than the maximum allowable gain (Gmax) of the ultra-high frequency amplifier 10 of FIG. 1.

Therefore, the ultra-high frequency amplifier 200 of FIG. 2 may have superior amplification characteristics than the ultra-high frequency amplifier 10 of FIG. 1 in an operating frequency region (a frequency band between 140 GHz and 180 GHz) having a high frequency.

FIG. 4B is a graph comparing the maximum frequencies (Fmax1 and Fmax2) when the maximum allowable gains (Gmax) of the ultra-high frequency amplifiers 10 and 200 of FIGS. 1 and 2 are zero.

In FIG. 4B, the horizontal axis may indicate a frequency, and the unit may be GHz. The vertical axis may indicate the maximum allowable gain (Gmax), and the unit may be dB. A duplicate description of a portion similar to that of FIG. 4A will be omitted.

As the operating frequency region increases, the operation of the amplifier may be limited. In detail, a transistor constituting an amplifier in a high frequency band such as terahertz may not provide power gain and current gain, and may cause loss. There may be the maximum frequency at which an amplifier may have a power gain and the maximum frequency at which the amplifier may have a current gain.

Referring to FIGS. 1, 2 and 4B, as indicated by a solid line and a dotted line, the maximum frequency Fmax2 at which the ultra-high frequency amplifier 200 of FIG. 2 may provide a power gain may have a value higher than the maximum frequency Fmax1 at which the ultra-high frequency amplifier 10 of FIG. 1 may provide a power gain.

FIG. 4C is a graph comparing current gains (H21) Imax of the ultra-high frequency amplifiers 10 and 200 of FIGS. 1 and 2.

In FIG. 4C, the horizontal axis may indicate a frequency, and the unit may be GHz. The vertical axis may indicate the current gain (H21) Imax, and the unit may be dB.

The current gain (H21) Imax may be defined by an H-parameter and expressed as the following equation.

H21=I2/I1|V2=0

Where H21 may mean the ratio of the current I2 of the output amplified RF signal to the current I1 of the inputted RF signal when the voltage V2 of the output terminal among H-parameters is ‘0’ (zero) (when the output terminal is short-circuited).

Referring to FIGS. 1, 2 and 4C, the solid line shows the current gain (H21) Imax of the ultra-high frequency amplifier 10 of FIG. 1. The current gain (H21) Imax may mean the ratio of the current of the RF signal amplified at the amplifier output terminal 15 to the current of the RF signal input to the amplifier input terminal 11. The dotted line shows the current gain (H21) Imax of the ultra-high frequency amplifier 200 of FIG. 2.

As indicated by the solid and dotted lines, in the operating frequency region (frequency band between 140 GHz and 180 GHz), the current gain (H21) Imax of the ultra-high frequency amplifier 200 of FIG. 2 may have a value substantially higher than the current gain (H21) Imax of the ultra-high frequency amplifier 10 of FIG. 1.

Accordingly, the ultra-high frequency amplifier 200 of FIG. 2 may have superior output characteristics than the ultra-high frequency amplifier 10 of FIG. 1 in the operating frequency region (frequency band between 140 GHz and 180 GHz) having a high frequency.

FIG. 4D is a graph comparing the maximum frequencies Ft1 and Ft2 when the current gains (H21) Imax of the ultra-high frequency amplifiers 10 and 200 of FIGS. 1 and 2 are zero.

In FIG. 4D, the horizontal axis may indicate a frequency, and the unit may be GHz. The vertical axis may indicate a current gain (H21) Imax, and the unit may be dB. A duplicate description of a diagram similar to that of FIG. 4C will be omitted.

Referring to FIGS. 1, 2 and 4D, as indicated by the solid and dotted lines, the maximum frequency Ft2 at which the ultra-high frequency amplifier 200 of FIG. 2 may provide the current gain (H21) Imax may have a value higher than the maximum frequency Ft1 at which the ultra-high frequency amplifier 10 of FIG. 1 may provide the current gain (H21) Imax.

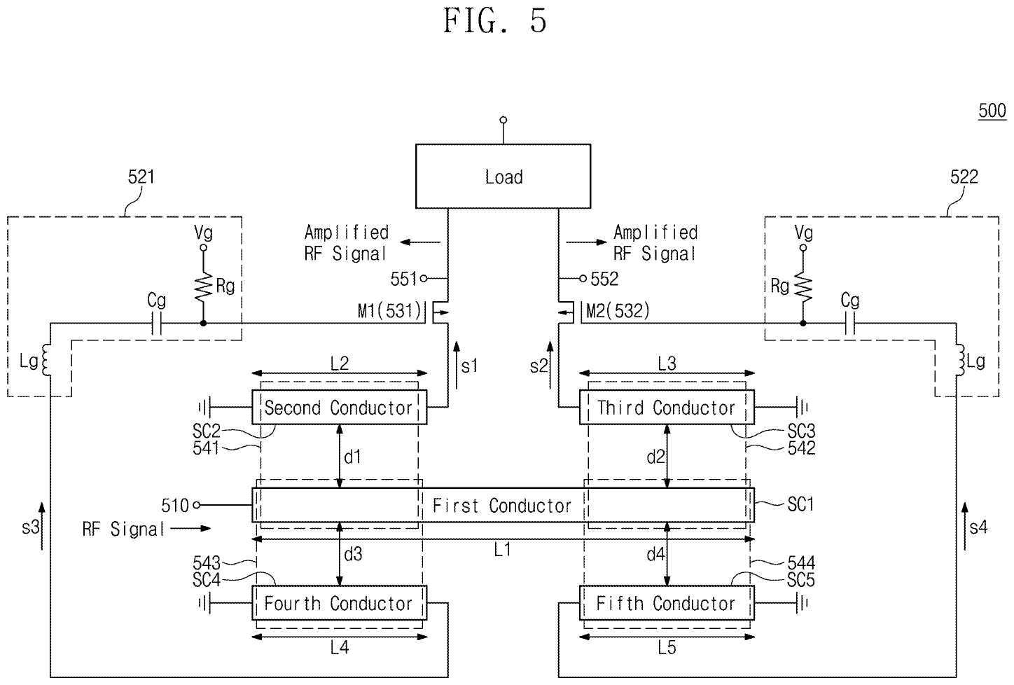

FIG. 5 is a diagram illustrating an ultra-high frequency amplifier 500 according to a third embodiment of the present disclosure. Referring to FIG. 5, the ultra-high frequency amplifier 500 may include an amplifier input terminal 510, first and second matching circuits 521 and 522, transistor 531 including a gate terminal connected to an output terminal of the first matching circuit 521, a second terminal connected to a first amplifier output terminal 551 and a first terminal, a second transistor 532 including a gate terminal connected to an output terminal of the second matching circuit 522, a second terminal connected to a second amplifier output terminal 552 and a first terminal, first to fourth baluns 541 to 544, and the first and second amplifier output terminals 551 and 552.

For example, the amplifier input terminal 510, the first and second matching circuits 521 and 522, the first and second transistors 531 and 532, and the first and second amplifier output terminals 551 and 552 of FIG. 5 correspond to the amplifier input terminals 11 and 210, the matching circuits 12 and 220, the transistors 13 and 230, and the amplifier output terminals 15 and 250 of FIGS. 1 and 2. Accordingly, overlapping descriptions of similar operations for each corresponding component will be omitted.

The ultra-high frequency amplifier 500 may include one or more conductors. For example, FIG. 5 illustrates the configurations of first to fifth conductors SC1 to SC5, but the embodiments are not limited thereto and may include six or more conductors.

One end of the first conductor SC1 may be connected to the amplifier input terminal 510 to receive an RF signal applied to the amplifier input terminal 510. An opposite end of the first conductor SC1 may be in an open state.

The second conductor SC2 may be arranged parallel to a first portion of the first conductor SC1. In detail, the second conductor SC2 may be arranged on a first side surface of the first conductor SC1, and may be arranged at a predetermined distance d1 from the first side surface of the first conductor SC1. One end of the second conductor SC2 may be connected to a ground terminal, and an opposite end of the second conductor SC2 may be connected to the first terminal of the first transistor 531.

The third conductor SC3 may be arranged parallel to a second portion of the first conductor SC1. In detail, the third conductor SC3 may be arranged separately from the second conductor SC2, and arranged on the first side surface of the first conductor SC1 while being spaced apart from the first side surface of the first conductor SC1 by a predetermined distance d2. One end of the third conductor SC3 may be connected to a ground terminal, and an opposite end of the third conductor SC3 may be connected to the first terminal of the second transistor 532.

The fourth conductor SC4 may be arranged parallel to a third portion of the first conductor SC1. The third portion may correspond to a side surface different from the first and second portions.

In detail, the fourth conductor SC4 may be arranged on a second side surface of the first conductor SC1 while being spaced apart from the second side surface of the first conductor SC1 by a predetermined distance d3. One end of the fourth conductor SC4 may be connected to the ground terminal, and an opposite end of the fourth conductor SC4 may be connected to an input terminal of the first matching circuit 521. The second side surface may be a side surface different from the first side surface.

The fifth conductor SC5 may be arranged parallel to a fourth portion of the first conductor SC1. The fourth portion may correspond to a side surface different from the first and second portions, and may correspond to the same side surface as the third portion.

In detail, the fifth conductor SC5 may be arranged separately from the fourth conductor SC4, and arranged on the second side surface of the first conductor SC1 while being spaced apart from the second side surface of the first conductor SC1 by a predetermined distance d4. One end of the fifth conductor SC5 may be connected to the ground terminal, and an opposite end of the fifth conductor SC5 may be connected to an input terminal of the second matching circuit 522.

The predetermined distance d1 between the first conductor SC1 and the second conductor SC2, the predetermined distance d2 between the first conductor SC1 and the third conductor SC3, the predetermined distance d3 between the first conductor SC1 and the fourth conductor SC4 and the predetermined distance d4 between the first conductor SC1 and the fifth conductor SC5 may be the same or may be different from each other. The ultra-high frequency amplifier 200 may adjust the input impedances of the first and second transistors 531 and 532 by adjusting the predetermined distances d1 to d4.

The lengths L2 to L5 of the second to fifth conductors SC2 to SC5 may all be the same, or all or some may be different. The ultra-high frequency amplifier 200 may adjust the input impedances of the first and second transistors 531 and 532 by adjusting the lengths L1 to L5 of the first to fifth conductors SC1 to SC5, respectively.

It has been described above that the first conductor SC1 and the second conductor SC2 may form the first balun 541 and that the first conductor SC1 and the third conductor SC3 may form the second balun 542.

The first conductor SC1 and the fourth conductor SC4 may form the third balun 543. The third balun 543 may output a third balance signal s3 based on the RF signal input to the amplifier input terminal 510. The third balance signal s3 may be output through an opposite end of the fourth conductor SC4.

The first conductor SC1 and the fifth conductor SC5 may form the fourth balun 544. The RF signal input to the amplifier input terminal 510 may be provided to the fourth balun 544 through the first conductor SC1. The fourth balun 544 may output a fourth balance signal s4 based on the RF signal input to the amplifier input terminal 510. The fourth balance signal s4 may be output through an opposite end of the fifth conductor SC5.

The phase of the first balance signal s1 output from the first balun 541 may precede the phase of the third balance signal s3 output from the third balun 543 by 180 degrees. Alternatively, the phase of the third balance signal s3 output from the third balun 543 may precede the phase of the first balance signal s1 output from the first balun 541 by 180 degrees.

The phase of the second balance signal s2 output from the second balun 542 may precede the phase of the fourth balance signal s4 output from the fourth balun 544 by 180 degrees. Alternatively, the phase of the second balance signal s2 output from the second balun 542 may precede the phase of the fourth balance signal s4 output from the fourth balun 544 by 180 degrees.

In this case, the first balance signal s1 and the third balance signal s3 may adjust the drain-source current amount of the first transistor 531 based on the gate input voltage Vg, and may reduce the amount of current leaking due to a parasitic component (internal capacitance, not shown) of the first transistor 531 by adjusting the drain-source current amount of the first transistor 531. The second balance signal s2 and the fourth balance signal s4 may adjust the drain-source current amount of the second transistor 532 based on the gate input voltage Vg.

The first transistor 531 may amplify the RF signal based on the first balance signal s1 output from the first balun 541 and the third balance signal s3 output from the third balun 543. The second transistor 532 may amplify the RF signal based on the second balance signal s2 output from the second balun 542 and the fourth balance signal s4 output from the fourth balun 544.

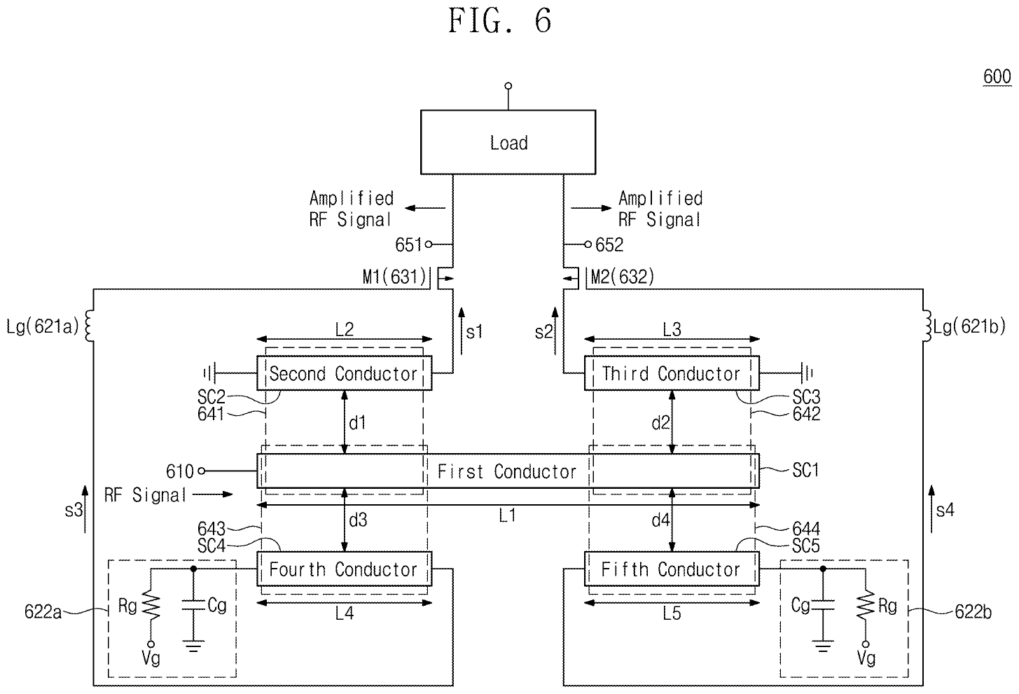

FIG. 6 is a diagram illustrating an ultra-high frequency amplifier 600 according to a fourth embodiment of the present disclosure. Referring to FIG. 6, the ultra-high frequency amplifier 600 may include an amplifier input terminal 610, first and second inductors (Lg) 621 and 622, first and second RC circuits 623 and 624, first and second transistors 631 and 632, first to fourth baluns 641 to 644, and first and second amplifier output terminals 651 and 652.

For example, the amplifier input terminal 610, the first and second transistors 631 and 632, the first to fourth baluns 641 to 644, and the first and second amplifier output terminals 651 and 652 of FIG. 6 correspond to the amplifier input terminal 510, the first and second transistors 531 and 532, the first to fourth baluns 541 to 544, and first and second amplifier output terminals 551 and 552 of FIG. 5. The first and second inductors (Lg) 621a and 621b and the first and second RC circuits 622a and 622b of FIG. 6 correspond to the inductor (Lg) 321 and the RC circuit 322 of FIG. 3, respectively. Accordingly, overlapping descriptions of similar operations for each corresponding component will be omitted.

The first inductor (Lg) 621a may have one end connected to an opposite end of the fourth conductor SC4 and an opposite end connected to the gate terminal of the first transistor 631. The first inductor (Lg) 621a may have a value matching a parasitic component (internal capacitance, not shown) of the first transistor 631.

The second inductor (Lg) 621b may have one end connected to an opposite end of the fifth conductor SC5 and an opposite end connected to the gate terminal of the second transistor 632. The second inductor (Lg) 621b may have a value matching a parasitic component (internal capacitance, not shown) of the second transistor 632.

An input power source (not shown) may adjust the gate input voltage Vg to allow the frequency of the RF signal input through the amplifier input terminal 610 to correspond to the resonance frequency at which the first inductor (Lg) 621a and the parasitic component (internal capacitance, not shown) of the first transistor 631 are matched.

The input power source (not shown) may adjust the gate input voltage Vg to allow the frequency of the RF signal input through the amplifier input terminal 610 to correspond to the resonance frequency at which the second inductor (Lg) 621b and the parasitic component (internal capacitance, not shown) of the second transistor 632 are matched.

The first and fourth conductors SC1 and SC4 may form the third balun 643. The third balun 643 may output the third balance signal s3 based on the RF signal input to the amplifier input terminal 610. The phase of the third balance signal s3 may vary according to values of the input resistor Rg and the capacitor Cg included in the first RC circuit 622a.

The first and fifth conductors SC1 and SC5 may form the fourth balun 644. The fourth balun 644 may output the fourth balance signal s4 based on the RF signal input to the amplifier input terminal 610. The phase of the fourth balance signal s4 may vary according to values of the input resistor Rg and the capacitor Cg included in the second RC circuit 622b.

The phase of the third balance signal s3 output from the third balun 643 that varies according to the values of the input resistor Rg and the capacitor Cg may be opposite to the phase of the first balance signal s1 output from the first balun 641.

The phase of the fourth balance signal s4 output from the fourth balun 644 that varies according to the values of the input resistor Rg and the capacitor Cg may be opposite to the phase of the second balance signal s2 output from the second balun 642.

In this case, the first balance signal s1 and the third balance signal s3 may adjust the drain-source current amount of the first transistor 631 based on the gate input voltage Vg. The second balance signal s2 and the fourth balance signal s4 may adjust the drain-source current amount of the second transistor 632 based on the gate input voltage Vg.

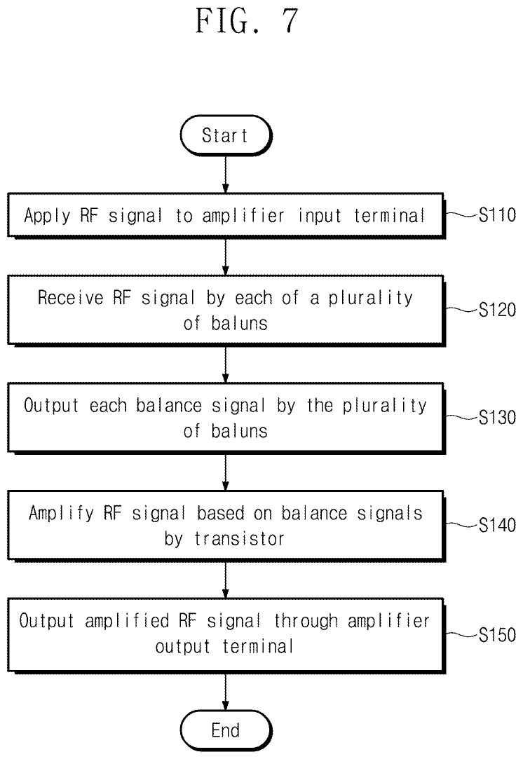

FIG. 7 is a flowchart illustrating a method of operating the ultra-high frequency amplifier 200 according to the first embodiment of the present disclosure.

Referring to FIGS. 2 and 7, in operation S110, the RF signal may be applied to the amplifier input terminal 210 of the ultra-high frequency amplifier 200. The ultra-high frequency amplifier 200 may receive the RF signal from a reception antenna (not shown) connected to the amplifier input terminal 210.

In operation S120, the first and second baluns 241 and 242 may receive the RF signal, respectively. The second balun 242 formed of the first conductor SC1 and the third conductor SC3 may receive the RF signal through the first conductor SC1 connected to the amplifier input terminal 210.

In operation S130, the first balun 241 formed of the first conductor SC1 and the second conductor SC2 may output the first balance signal s1 based on the RF signal. The second balun 242 formed of the first conductor SC1 and the third conductor SC3 may output the second balance signal s2 based on the RF signal.

In operation S140, the transistor 230 may amplify the RF signal based on the first and second balance signals s1 and s2. The phase of the first balance signal s1 may be opposite to the phase of the second balance signal s2. The first balance signal s1 and the second balance signal s2 may adjust the drain-source current amount of the transistor 230. The transistor 230 may amplify the RF signal by performing an amplification operation.

In operation S150, the amplified RF signal may be output through the amplifier output terminal 250. The amplified RF signal may be output through the amplifier output terminal 250 when the transistor 230 is turned off.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. An ultra-high frequency amplifier comprising:
a first conductor connected to an amplifier input terminal to receive an RF signal applied to the amplifier input terminal;
a second conductor parallel to a first portion of the first conductor;
a third conductor separated from the second conductor and parallel to a second portion of the first conductor; and
a transistor including a gate terminal connected to one end of the second conductor, a first terminal connected to one end of the third conductor, and a second terminal connected to an amplifier output terminal,
wherein the first conductor and the second conductor form a first balun to output a first balance signal based on the RF signal,
the first conductor and the third conductor form a second balun to output a second balance signal based on the RF signal, and
the first balance signal and the second balance signal output from the first balun and the second balun, respectively, control an amount of drain-source current of the transistor.

2. The ultra-high frequency amplifier of claim 1, further comprising:
an inductor connected between the gate terminal of the transistor and one end of the second conductor.

3. The ultra-high frequency amplifier of claim 1, further comprising:
an input resistor having one end connected to the gate terminal of the transistor and an opposite end connected to a gate bias terminal to which a gate input voltage is applied.

4. The ultra-high frequency amplifier of claim 1, wherein a phase of the first balance signal is opposite to a phase of the second balance signal.

5. The ultra-high frequency amplifier of claim 1, wherein a length of the second conductor is different from a length of the third conductor.

6. The ultra-high frequency amplifier of claim 1, wherein one end of the second conductor is connected to the gate terminal of the transistor, and
wherein the ultra-high frequency amplifier further comprises an input resistor having one end connected to an opposite end of the second conductor and an opposite end connected to a gate bias terminal to which a gate input voltage is applied.

7. An ultra-high frequency amplifier comprising:
a first conductor connected to an amplifier input terminal to receive an RF signal applied to the amplifier input terminal;
a second conductor parallel to a first portion of the first conductor;
a third conductor separated from the second conductor and parallel to a second portion of the first conductor;
a fourth conductor parallel to a third portion of the first conductor;
a fifth conductor separated from the fourth conductor and parallel to a fourth portion of the first conductor;
a first transistor including a first terminal connected to one end of the second conductor, a gate terminal connected to one end of the fourth conductor, and a second terminal connected to an amplifier output terminal; and
a second transistor including a first terminal connected to one end of the third conductor, a gate terminal connected to one end of the fifth conductor, and a second terminal connected to the amplifier output terminal,
wherein the first conductor and the second conductor form a first balun to output a first balance signal based on the RF signal,
the first conductor and the third conductor form a second balun to output a second balance signal based on the RF signal,
the first conductor and the fourth conductor form a third balun to output a third balance signal based on the RF signal,
the first conductor and the fifth conductor form a fourth balun to output a fourth balance signal based on the RF signal,
the first balance signal and the third balance signal output from the first balun and the third balun, respectively, control an amount of drain-source current of the first transistor, and
the second balance signal and the fourth balance signal output from the second balun and the fourth balun, respectively, control an amount of drain-source current of the second transistor.

8. The ultra-high frequency amplifier of claim 7, further comprising:
a first inductor connected between the gate terminal of the first transistor and one end of the fourth conductor; and
a second inductor connected between the gate terminal of the second transistor and one end of the fifth conductor.

9. The ultra-high frequency amplifier of claim 7, further comprising:
a first input resistor having one end connected to the gate terminal of the first transistor and an opposite end connected to a gate bias terminal to which a gate input voltage is applied; and
a second input resistor having one end connected to the gate terminal of the second transistor and an opposite end connected to the gate bias terminal to which the gate input voltage is applied.

10. The ultra-high frequency amplifier of claim 7, wherein a phase of the first balance signal is opposite to a phase of the third balance signal.

11. The ultra-high frequency amplifier of claim 7, wherein a phase of the second balance signal is opposite to a phase of the fourth balance signal.

12. The ultra-high frequency amplifier of claim 7, wherein a length of the second conductor is different from a length of the fourth conductor.

13. The ultra-high frequency amplifier of claim 7, wherein a length of the third conductor is different from a length of the fifth conductor.

14. The ultra-high frequency amplifier of claim 7, wherein one end of the fourth conductor is connected to the gate terminal of the first transistor,
wherein one end of the fifth conductor is connected to the gate terminal of the second transistor, and
wherein the ultra-high frequency amplifier further comprises a first input resistor having one end connected to an opposite end of the fourth conductor and an opposite end connected to a gate bias terminal to which a gate input voltage is applied, and a second input resistor having one end connected to an opposite end of the fifth conductor and an opposite end connected to the gate bias terminal to which the gate input voltage is applied.
